(19) United States
(12) Patent Application Publication
(10) Pub. No.: US 2024/0329001 A1
(43) Pub. Date: Oct. 3, 2024

(54) QUARTZ CRYSTAL MICROBALANCE (QCM) SENSOR HAVING RAPID REGISTRATION RESPONSE

(71) Applicant: INFICON, Inc., East Syracuse, NY (US)

(72) Inventors: David Y. Lee, Manlius, NY (US); Chunhua Song, Jamesville, NY (US); Mohamed Buhary Rinzan, Manlius, NY (US)

(73) Assignee: INFICON, Inc., East Syracuse, NY (US)

(21) Appl. No.: 18/580,234

(22) PCT Filed: Jul. 15, 2022
(86) PCT No.: PCT/US2022/037256

§ 371 Date: Jan. 18, 2024

Related U.S. Application Data
(60) Provisional application No. 63/223,333, filed on Jul. 19, 2021.

(51) Int. Cl. G01N 29/036; G01N 5/02

(52) U.S. Cl. CPC G01N 29/036; G01N 5/02

(57) ABSTRACT

An improved Quartz Crystal Microbalance (QCM) sensor and method for fabrication thereof by one of: (i) increasing the quantity of surface defects to the quartz crystal surface and (ii) an adsorption of non-metal and/or metalloid elements to the quartz crystal surface. The improved sensor, and the method for its fabrication, significantly improves the registration response of the QCM sensor from minutes to several seconds.

### CROSS REFERENCE TO RELATED APPLICATIONS

Pursuant to relevant portions of 35 U.S.C. § 119 and 37 C.F.R. § 1.53, this application claims the benefit and priority of U.S. Patent Application 63/223,333, filed on Jul. 19, 2021, the entire contents of which is hereby incorporated by reference.

### BACKGROUND

Deposition and etch processes are two of the key steps at the production sites of myriads of industries. An integrated group of sensors, such as mass spectrometers, optical spectrometers, RF sensors, and vacuum gauges, is often employed at manufacturing plants to monitor these processes. While these sensors provide detailed information regarding the materials deposited or removed from the substrate, it requires significant effort to correlate the data collected by these sensors to monitor the actual accumulation or removal of film on substrates located in the various chambers.

One of the best known and most versatile sensors employed to monitor film growth rate is a Quartz Crystal Microbalance (QCM) sensor. These sensors, also known as Quartz MicroBalance (QMB) and Quartz Crystal Nanobalance (QCN), measure a mass variation by measuring a change in the resonance frequency of the quartz crystal. The resonance frequency varies by the addition or deletion of mass to the crystal surface due to film deposition/removal on the surface of the acoustic resonator.

In a typical deposition process, the material to be coated on a target substrate arrives from a source by evaporation or sublimation and condenses on the substrate to form a desired film. The physical and electrical properties of this film is often determined by factors such as substrate temperature and material condensation rate, hence; it is critical to have total control of the rate of evaporation/sublimation prior to the actual deposition on the substrate. A QCM sensor is placed in the vicinity of the substrate and functions as a surrogate to reflect a rate of deposition and accumulated thickness. QCM sensors are proven to be an effective, either passively or actively, means for controlling the deposition process via a strong correlation between the source evaporation rate and the QCM detected rate.

A QCM sensor is a consumable device which must be regularly and routinely replaced in a continuous substrate manufacturing process. Conventional QCM sensors perform over a prescribed period of time (i.e., on the order of minutes to hours), and, as one QCM sensor is exhausted, another must be exchanged in-situ to the monitoring position while deposition process continues. More specifically, several QCMs may be housed in a carousel and rotated sequentially to replace each consumed crystal during a process monitoring. In general, only one QCM is used for monitoring a particular location at a given time. When this QCM sensor reaches the end of its useful life, it is replaced by advancing a new QCM sensor located in-situ beneath the shuttered portion of the carousel.

In theory, each newly replaced crystal should instantaneously register the previously established evaporation rate of the source for optimum manufacturing control. Unfortunately for many depositing materials, QCM sensors typically exhibit a short, yet significant, delay before reaching an accurate steady state response, i.e., the response time required to accurately register the correct rate of material deposition. Such delay may trigger a power source to react falsely, send an incorrect signal to the source control resulting in a temporary increase in evaporation/sublimation power leading to significant error in a substrate's true film thickness. While for some materials this is negligible, others have triggered a variety of unsuccessful efforts to relieve the difficulties caused by delays in QCM sensor monitoring.

Magnesium is one of many materials that QCM sensors show significant delay in initial detection. There are currently no solutions available for a rapid response or registration of the true magnesium deposition rate. In order to mitigate the response delay, operators have been known to pre-coat the QCM crystals with a small amount of magnesium in the same process chamber prior to receiving actual measurements. This additional step is laborious, adds material cost, and cannot be performed as part of the crystal production. In addition, surface layers pre-coated with magnesium cannot survive exposure to atmosphere for any prolonged period for the purpose of convenient transportation and/or storage.

A need, therefore, exists for a QCM sensor which provides rapid detection or registration of the true source flux in a Mg coating deposition process.

### BRIEF SUMMARY OF THE DISCLOSURE

In one embodiment of the disclosure, a method for fabricating a Quartz Crystal Microbalance (QCM) sensor is provided for monitoring semiconductor processes comprises the steps of: (i) providing a quartz crystal configured to measure a mass of materials deposited on a surface of the quartz crystal, and, (ii) modifying the surface of the quartz crystal by increasing the number of surface defects per unit area thereby increasing the surface area for rapid deposition of mass. The mass variation of the quartz crystal is registered as a consequence of a change in the resonance frequency of the quartz crystal when pulsed by a source of alternating current. The surface modification augments the registration response of the QCM sensor when exposed to deposition processes.

In another embodiment, a Quartz Crystal Microbalance (QCM) sensor is used for monitoring thin film deposition processes with the quartz crystal disc disposed between a pair of conductive electrodes, and the quartz crystal disc is configured to measure a film mass accumulated on a surface of the quartz crystal disc. The surface of the quartz crystal disc is modified such that the number of defects are increased above a threshold number per unit area along the surface. The mass variation is registered as a consequence of a change in resonance frequency of the quartz crystal disc when pulsed by a source of alternating current. The modified surface increases the surface area for rapid deposition of mass to augment the registration response of the QCM sensor.

In one embodiment of the disclosure, the amount of surface defects, in the nanometer to sub-millimeter scale range, of the QCM's electrode surface is significantly increased. In a microscopic sense, the created surface structural defects can be in the forms of pits, edges, islands or in any combination of them.

In another embodiment, non-metallic elements (such as hydrogen, helium, nitrogen, oxygen, fluorine, neon, chlorine, argon, krypton, xenon, radon, bromine, carbon, phosphorus, sulfur, selenium, and iodine) and metalloid elements (such as boron, silicon, germanium, arsenic, antimony, and tellurium) are adsorbed to the crystal electrode surface. The added elements on the surface can be of single species or in any form of mixed-species combinations among the non-metallic and/or metalloid elements. Furthermore, the structure of these added non-metal and metalloid elements formed on the surface can be in any form, including adatoms, clusters, ordered or non-ordered nano-patterns, and a partial, full, or multi-layer.

The above embodiments are exemplary only. Other embodiments as described herein are within the scope of the disclosed subject matter.

### BRIEF DESCRIPTION OF THE DRAWINGS

So that the manner in which the features of the disclosure can be understood, a detailed description may be had by reference to certain embodiments, some of which are illustrated in the accompanying drawings. It is to be noted, however, that the drawings illustrate only certain embodiments and are therefore not to be considered limiting of its scope, for the scope of the disclosed subject matter encompasses other embodiments as well. The drawings are not necessarily to scale, emphasis generally being placed upon illustrating the features of certain embodiments. In the drawings, like numerals are used to indicate like parts throughout the various views, in which:

FIG. 1 is an isolated perspective view of a Quartz Crystal Microbalance (QCM) sensor having a quartz crystal disc disposed between conductive electrodes along each face of the disc;

FIG. 2A is a bottom view of the Quartz Crystal Microbalance (QCM) sensor shown in FIG. 1;

FIG. 2B is a top view of the Quartz Crystal Microbalance (QCM) sensor shown in FIG. 1;

FIG. 3 is a magnified view of a treated Quartz Crystal Microbalance (QCM) sensor surface fabricated in accordance with the teachings of the present disclosure wherein the sensor surface has been topologically modified. The topological modifications increase the surface defects within a fixed area to enhance the response rate of the sensor;

FIG. 4 is a magnified view of a modified Quartz Crystal Microbalance (QCM) sensor wherein the sensor surface in the sub-micrometer square scale has been treated by the adsorption of non-metal and metalloid elements to enhance the response rate of the QCM sensor;

FIG. 5 is a magnified view of a modified QCM sensor surface in the sub-micrometer square scale wherein the sensor surface has been: (i) topologically modified to increase the quantity of surface defects, and (ii) treated by adsorption of non-metal and metalloid elements for the purpose of enhancing the response rate of the QCM sensor;

FIG. 6 is a graph comparing the rate of response associated with a conventional QCM sensor vs. the rate of response associated with a modified/treated QCM sensor fabricated in accordance with the teachings of the present disclosure;

FIG. 7 is a graph comparing the rate of response associated with a plurality of conventional QCM sensors vs. the rate of response associated with the same number of modified/treated QCM sensors; and

FIG. 8 is a graph comparing the overall sensor stability in deposition rate monitoring of conventional vs. modified/treated QCM sensors over a period of multiple hours.

Corresponding reference characters indicate corresponding parts throughout several views. The examples set out herein illustrate several embodiments, but should not be construed as limiting in scope in any manner.

### DETAILED DESCRIPTION

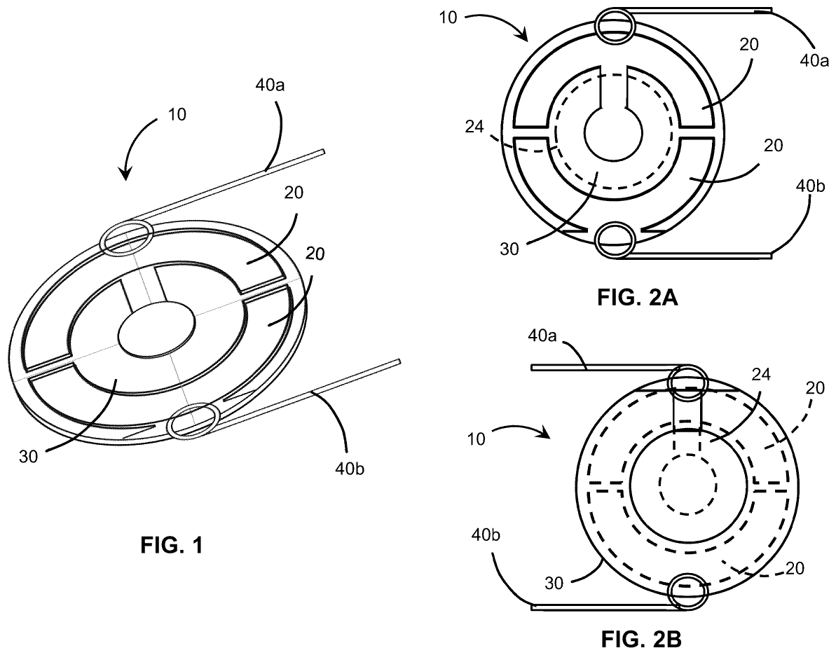

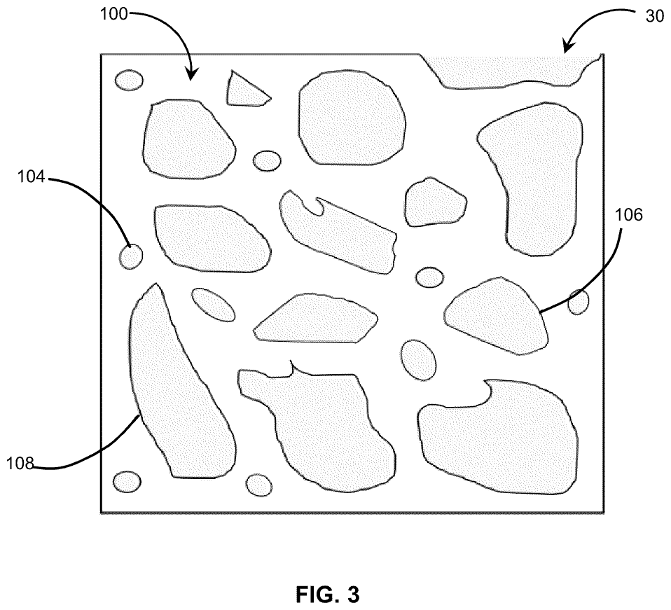

In FIGS. 1, 2A and 2B, perspective, bottom and plan views of a Quartz Crystal Microbalance (QCM) sensor 10, respectively, include conductive electrodes 20, 24 disposed on each face of a quartz crystal disc 30. A pair of connectors 40a, 40b are disposed on each side of the quartz crystal disc 30 and connect to each of the conductive electrodes 20, 24 to register changes in frequency of the quartz crystals as it changes in mass, i. e., in response to deposition and/or etch processes. In use, a QCM sensor 10 is placed in the vicinity of an area or region to be monitored in a process chamber of a semiconductor or Organic Light Emitting Diode (OLED) fabrication system. Changes to the surface of the QCM can be correlated to the same processes being performed on a surface of a substrate material in the process chamber. More specifically, the QCM sensor 10 has a resonance property which changes upon deposition of materials. The changes in mass alter the resonance response of the QCM crystal which is indicative of the anticipated changes occurring on the surface of the substrate.

As mentioned in the background of the invention, QCM sensors 10 are consumable and must be periodically replaced during the course of a production cycle. Furthermore, such QCM sensors 10 typically require a small yet significant time period to acclimate to process conditions before registering an accurate response. In an effort to increase the response rate of the QCM sensors 10, the inventors recognized that surface modification of the QCM sensors 10 can significantly diminish the time required to acclimate a QCM sensor 10 to process chamber conditions.

In FIG. 3, a first modified QC surface 100 of a Quartz Crystal (QC) 30 is fabricated in accordance with the teachings of the present disclosure. Therein, the QC surface 100 shows a plurality of topological indentations, imperfections and contour lines/edges 104, 106, 108, i.e., hereinafter collectively referred to as surface modifications or surface defects, over a surface area in the sub-micrometer scale. As illustrated, the increased percentage of 104, 106, 108 defects within the fixed area enhances the sensor's ability to adhere deposited materials efficiently and rapidly. More specifically, the surface modification is on the scale of: (i) angstroms to (ii) tens of nano-meters. At this extremely small size, i.e., comparable to the size of atoms and molecules, the surface defects can effectively capture deposited atoms or molecules. The surface modification on the electrode increases the efficacy and capacity of the QCM to monitor deposited atoms or molecules.

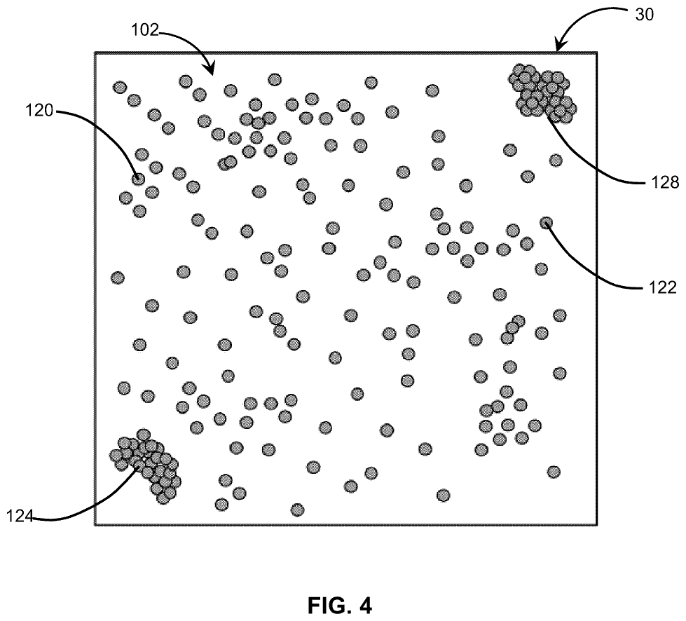

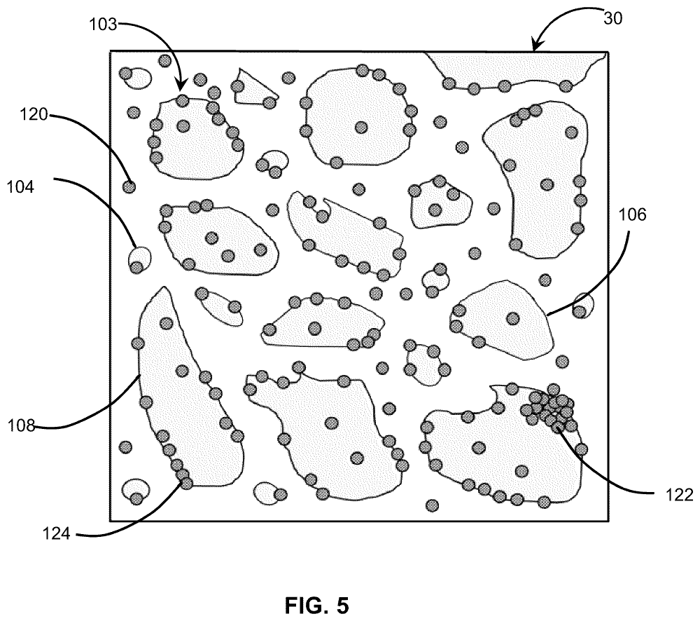

In FIG. 4, another embodiment of the disclosure includes a treated surface 102 having non-metallic and/or metalloid elements 120, 122 adsorbed by the QC in a sub-micrometer square to enhance the response rate of the QCM sensor 30. The non-metallic elements 120 may comprise elements from the group of: hydrogen, helium, nitrogen, oxygen, fluorine, neon, chlorine, argon, krypton, xenon, radon, bromine, carbon, phosphorous, sulfur, selenium, and iodine. The metalloid elements 122 may comprise elements from the group of: boron, silicon, germanium, arsenic, antimony, and tellurium. The structure of these added nonmetallic and metalloid elements 120, 122 can be in a variety of forms including adatoms, clusters, and ordered or non-ordered nano patterns The surface distribution of the nonmetallic and/or metalloid elements may also have a variety of forms, including a random distribution, an irregular grouping 124 (shown in the lower left corner), or a patterned grouping 128 (shown in the upper right corner).

In FIG. 5, another embodiment shows a modified/treated QCM surface 103 including surface modifications 104, 106, 108, each representing the addition of pits over a sub-micrometer square in area dimension (such as those shown in FIG. 3), in combination with adsorbed nonmetallic and/or metalloid elements 120, 122 such as those described in connection with FIG. 4). The QCM sensor surface 103 has been: (i) modified by increasing the quantity of surface defects, and (ii) treated by adsorption of non-metalloid elements 120, 122 elements. Hence, at least one of the foregoing surface treatments may be performed to enhance the response rate of a QCM sensor 30.

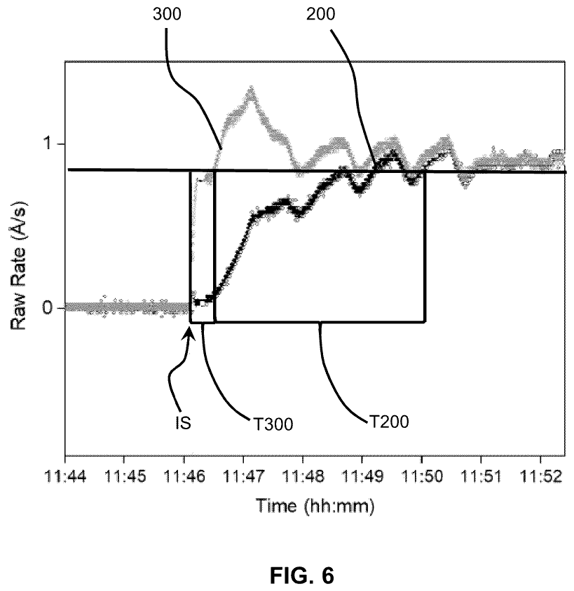

In FIG. 6, a graph depicts a comparison between a conventional QCM sensor and a modified QCM sensor. The graph plots the response rate (at 10 Hz data collection speed) over time (in minutes) in connection with a first curve 200 associated with a prior art conventional QCM sensor and a second curve 300 associated with a modified QCM sensor. An examination of curve 200 reveals a gradual increase in performance over a period of time T200 of about 4-5 minutes. A steady state condition is reached when the curve 200 yields a steady response—at which time performance is optimized. Examination of curve 300 reveals a nearly instantaneous rise in performance, over a time period T300 in less than about 5 seconds, to reach an optimal performance condition. Hence, the modified QCM sensor provides a significant improvement in performance readiness as compared to the conventional QCM sensor.

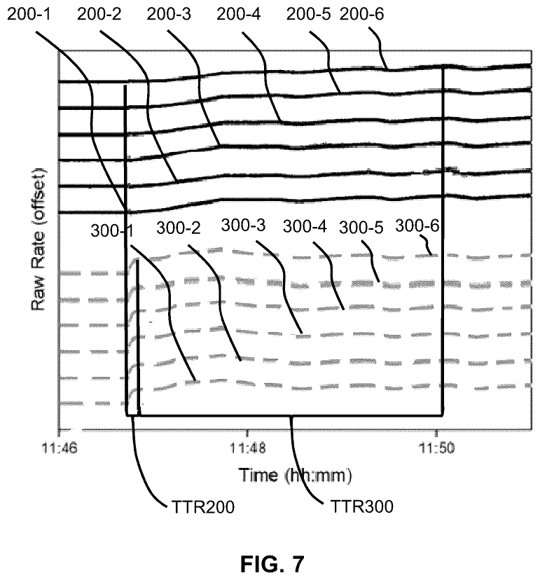

In FIG. 7, a graph depicts a comparison between a plurality of conventional QCM sensors and modified QCM sensors. The graph plots the response rate for as many as six conventional vs. six modified sensors. An examination of curves 200-1, 200-2, 200-3, 200-4, 200-5, and 200-6 reveals that all six conventional QCM sensors 30 exhibit a gradual rise in performance over the course of a period TTR200 or about 4-5 minutes. On the other hand, curves 300-1, 300-2, 300-3, 300-4, 300-5, and 300-6, associated with the modified QCM sensors, depict a nearly instantaneous response rate over the course of a period TTR300 of about just a few seconds. Once again, this graph illustrates the degree of consistency achievable when employing modified QCM sensors.

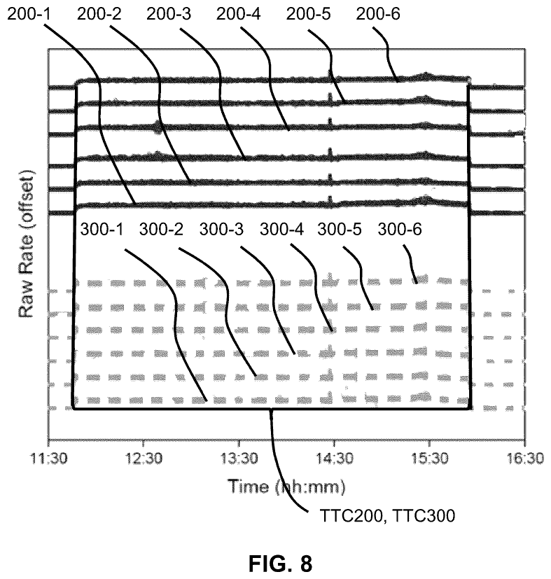

In FIG. 8, a graph depicts the response rate over a full production cycle of about five hours for a plurality of conventional QCM sensors and a plurality modified QCM sensors. Specifically, the graph plots the response rate for six conventional vs. six modified sensors. An examination of curves 200-1, 200-2, 200-3, 200-4, 200-5, and 200-6 reveals that all six conventional QCM sensors exhibit stable rate-monitoring performance over a period TTC200 of a four-to-five hour (4-5 hour) production cycle. Similarly, curves 300-1, 300-2, 300-3, 300-4, 300-5, and 300-6 exhibit the same performance characteristics over the same time period TTC300 (TTC300=TTC200). Hence, there is no loss in performance as a consequence of treating the QCM sensors.

In summary the crystals made by prior-art methods have surface roughness in the tenth of micro-meter scale, i.e., too large when comparing the size of deposited atoms or molecules. In other words, within a randomly chosen nano-meter scale area the electrode surface looks locally as if it is in general flat. In the present disclosure external bombardment of atoms, molecules and/or ions creates extremely small surface defects on the scale of angstroms to tens of nano-meters. At this extremely small size, i.e., comparable to the size of atoms and molecules, the defects can effectively capture the deposited atoms or molecules. This large amount of surface defects increases the capacity of the QCM electrode when monitoring the deposited atoms or molecules.

In one embodiment, the desired size and amount of defects on the crystal surface 30 is produced while maintaining the underlying electrode-quartz interface, i.e., having its conventional smooth surface. The external bombardment of atoms, molecules and/or ions is carefully selected and precisely controlled to bombard the surface with over a threshold period of time and amount of energy during the treatment process. In one condition, if the bombarding energy is too low, the defects cannot be effectively created, and, in another condition, if the treatment time is inadequate, the amount of surface defects per unit area may be insufficient. In yet other conditions, exceedingly large bombardment energy or overly lengthy treatment can destroy the QCM electrode surface which makes the acoustic waves randomly scattered and incoherent. As a result the QCM becomes unstable for accurate rate/thickness monitoring.

Additional embodiments include any one of the embodiments described above, where one or more of its components, functionalities or structures is interchanged with, replaced by or augmented by one or more of the components, functionalities or structures of a different embodiment described above.

It should be understood that various changes and modifications to the embodiments described herein will be apparent to those skilled in the art. Such changes and modifications can be made without departing from the spirit and scope of the present disclosure and without diminishing its intended advantages. It is therefore intended that such changes and modifications be covered by the appended claims.

Although several embodiments of the disclosure have been disclosed in the foregoing specification, it is understood by those skilled in the art that many modifications and other embodiments of the disclosure will come to mind to which the disclosure pertains, having the benefit of the teaching presented in the foregoing description and associated drawings. It is thus understood that the disclosure is not limited to the specific embodiments disclosed herein above, and that many modifications and other embodiments are intended to be included within the scope of the appended claims. Moreover, although specific terms are employed herein, as well as in the claims which follow, they are used only in a generic and descriptive sense, and not for the purposes of limiting the present disclosure, nor the claims which follow.

What is claimed is:

1. A method for fabricating a Quartz Crystal Microbalance (QCM) sensor used for monitoring semiconductor processes, comprising the steps of:
providing a quartz crystal configured to measure a mass deposited on a surface of the quartz crystal, the mass difference registered as a consequence of a change in resonance frequency of the quartz crystal;
modifying the surface of the quartz crystal;
wherein the step of modifying the surface increases a quantity of surface defects for rapid capturing of mass, thereby augmenting a registration response of the QCM sensor.

2. The method according to claim 1, further comprising the step of:
attaching non-metalloid elements to the modified surface.

3. The method according to claim 1, further comprising the step of:
attaching metalloid elements to the modified surface.

4. The method according to claim 2, wherein the non-metalloid elements are from a group comprising:
hydrogen, helium, nitrogen, oxygen, fluorine, neon, chlorine, argon, krypton, xenon, radon, bromine, carbon, phosphorous, sulfur, selenium, and iodine.

5. The method according to claim 3, wherein the metalloid elements are from a group comprising:
boron, silicon, germanium, arsenic, antimony, and tellurium.

6. The method according to claim 2, wherein the step of attaching non-metalloid elements is performed by adsorption.

7. The method according to claim 3, wherein the step of attaching metalloid elements is performed by adsorption.

8. The method according to claim 1, wherein the step of modifying the surface includes the step of increasing the quantity of defects to the sub-micrometer scale.

9. The method according to claim 1, wherein the step of modifying the surface includes a surface modification on the order of angstroms.

10. The method according to claim 1, wherein the step of modifying the surface includes a surface modification on the order of tenths of nano-meters.

11. A Quartz Crystal Microbalance (QCM) sensor used for monitoring thin film deposition processes, comprising:
a quartz crystal disc disposed between a pair of conductive electrodes, which quartz crystal disc is configured to measure a mass accumulation on a surface of the quartz crystal, the mass variation registered as a consequence of a change in resonance frequency of the quartz crystal;
the surface of the quartz crystal being modified by increasing the quantity of surface defects to augment a registration response of the quartz crystal.

12. The QCM sensor of claim 11, further comprising metalloid elements attached to the modified surface of the quartz crystal.

13. The QCM sensor of claim 11, further comprising non-metalloid elements attached to the modified surface of the quartz crystal.

14. The QCM sensor of claim 11, further comprising a combination of non-metalloid and metalloid elements attached to the modified surface of the quartz crystal.

15. The QCM sensor of claim 14,
wherein the metalloid elements include elements from a group of:
hydrogen, helium, nitrogen, oxygen, fluorine, neon, chlorine, argon, krypton, xenon, radon, bromine, carbon, phosphorous, sulfur, selenium, and iodine; and
wherein the non-metalloid elements include elements from a group of:
boron, silicon, germanium, arsenic, antimony, and tellurium.

16. A method for fabricating a Quartz Crystal Microbalance (QCM) sensor used for rapid registering of an established deposition rate, comprising the steps of:
increasing the area percentage of defects of the QCM surface.

17. The method according to claim 16, further comprising the step of:
treating the QCM surface with non-metalloid elements.

18. The method according to claim 16, further comprising the step of:
treating the QCM surface with metalloid elements.

19. The method according to claim 17, wherein the non-metalloid elements comprise elements from the a group comprising:
hydrogen, helium, nitrogen, oxygen, fluorine, neon, chlorine, argon, krypton, xenon, radon, bromine, carbon, phosphorous, sulfur, selenium, and iodine.

20. The method according to claim 18, wherein the metalloid elements comprise elements from the a group comprising:
boron, silicon, germanium, arsenic, antimony, and tellurium.

21. The method according to claim 16, including the steps of:
treating the QCM surface with non-metalloid elements, and
treating the QCM surface with metalloid elements.

22. The method according to claim 21, wherein the step of treating the QCM surface includes thin film deposition from the group of: atomic layer deposition, chemical vapor deposition, atomic or ion beam bombardment, and high-voltage sputtering.

23. The method according to claim 16, wherein the step of increasing the percentage of defects to the QCM surface is accomplished within a reaction environment including liquid, gas and plasma phase environments.

24. The method of claim 16, further comprising the step of:
removing/detaching materials from the quartz crystal surface in order to the surface modifications.

25. The QCM sensor of claim 15, wherein precursors/reagents needed to achieve the surface adsorption can be in one of a chemical and a physical form including atoms, ions, radicals and combinations thereof.

26. The QCM sensor of claim 15, wherein the surface modification is performed on existing quartz crystals.
